(19) United States
(12) Patent Application Publication
(10) Pub. No.: US 2024/0071908 A1
(43) Pub. Date: Feb. 29, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventors: Shoji TAKEI, Kyoto (JP); Akinori NII, Kyoto (JP)

(73) Assignee: ROHM CO., LTD., Kyoto (JP)

(21) Appl. No.: 18/454,185

(22) Filed: Aug. 23, 2023

(30) Foreign Application Priority Data
Aug. 26, 2022 (JP) 2022-134922

(51) Int. Cl. H01L 23/522; H01L 21/768; H01L 21/784; H01L 23/528; H01L 23/532

(52) U.S. Cl. CPC H01L 23/5226; H01L 21/76802; H01L 21/76877; H01L 21/76892; H01L 21/784; H01L 23/528; H01L 23/53238

(57) ABSTRACT

A semiconductor device includes an interlayer insulating film, and a wiring of an uppermost layer arranged on the interlayer insulating film, wherein the wiring includes a seed layer arranged on the interlayer insulating film and a wiring body portion arranged on the seed layer, wherein a constituent material of the wiring body portion is copper or a copper alloy, and wherein a trench is formed in an upper surface of the interlayer insulating film along an outer edge of the interlayer insulating film in a plan view.

### CROSS-REFERENCE TO RELATED APPLICATION

This application is based upon and claims the benefit of priority from Japanese Patent Application No. 2022-134922, filed on Aug. 26, 2022, the entire contents of which are incorporated herein by reference.

### TECHNICAL FIELD

The present disclosure relates to a semiconductor device and a method of manufacturing a semiconductor device.

### BACKGROUND

For example, the related art discloses a semiconductor device. The semiconductor device disclosed in the related art includes an interlayer insulating film and a wiring which is an uppermost layer arranged on the interlayer insulating film. The wiring includes a seed layer and a wiring main body portion arranged on the seed layer. The constituent material of the wiring main body portion is copper or a copper alloy.

### BRIEF DESCRIPTION OF DRAWINGS

The accompanying drawings, which are incorporated in and constitute a part of the specification, illustrate embodiments of the present disclosure.

FIG. 1 is a plan view of a semiconductor device.

FIG. 2 is a cross-sectional view taken along line II-II in FIG. 1.

FIG. 3 is a manufacturing process diagram of the semiconductor device.

FIG. 4 is a plan view of a semiconductor substrate prepared in a preparation step S1.

FIG. 5 is a cross-sectional view for explaining an element isolation step S2.

FIG. 6 is a cross-sectional view for explaining a first ion implantation step S3.

FIG. 7 is a cross-sectional view for explaining a gate insulating film formation step S4.

FIG. 8 is a cross-sectional view for explaining a gate formation step S5.

FIG. 9 is a cross-sectional view for explaining a second ion implantation step S6.

FIG. 10 is a cross-sectional view for explaining a sidewall spacer formation step S7.

FIG. 11 is a cross-sectional view for explaining a third ion implantation step S8.

FIG. 12 is a cross-sectional view for explaining a first interlayer insulating film formation step S9.

FIG. 13 is a cross-sectional view for explaining a contact plug formation step S10.

FIG. 14 is a cross-sectional view for explaining a first wiring formation step S11.

FIG. 15 is a cross-sectional view for explaining a second interlayer insulating film formation step S12.

FIG. 16 is a cross-sectional view for explaining a first via plug formation step S13.

FIG. 17 is a cross-sectional view for explaining a second wiring formation step S14.

FIG. 18 is a cross-sectional view for explaining a third interlayer insulating film formation step S15.

FIG. 19A is a first cross-sectional view for explaining a second via plug formation step S16.

FIG. 19B is a second cross-sectional view for explaining the second via plug formation step S16.

FIG. 20 is a cross-sectional view for explaining a trench formation step S17.

FIG. 21 is a cross-sectional view for explaining a seed layer formation step S18a.

FIG. 22 is a cross-sectional view for explaining an electrolytic plating step S18b.

FIG. 23 is a cross-sectional view for explaining an etching step S18c.

FIG. 24 is a cross-sectional view of a semiconductor device.

FIG. 25 is a manufacturing process diagram of the semiconductor device.

FIG. 26A is a first cross-sectional view for explaining a second via plug formation step S16 in a manufacturing method of the semiconductor device.

FIG. 26B is a second cross-sectional view for explaining the second via plug formation step S16 in the manufacturing method of the semiconductor device.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Details of embodiments of the present disclosure will be described with reference to the drawings. Throughput the drawings, the same or corresponding parts are denoted by the same reference numerals, and duplicate explanation thereof will not be repeated.

### First Embodiment

A semiconductor device according to a first embodiment will be described. The semiconductor device according to the first embodiment is referred to as a semiconductor device 100A.

### <Configuration of Semiconductor Device 100A>

A configuration of the semiconductor device 100A will be described below.

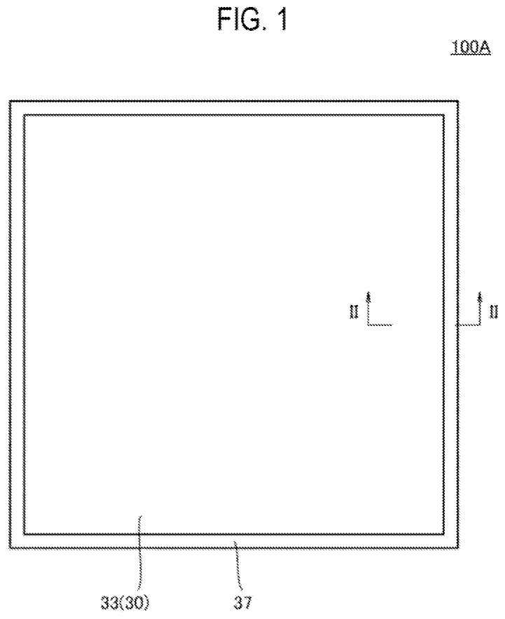

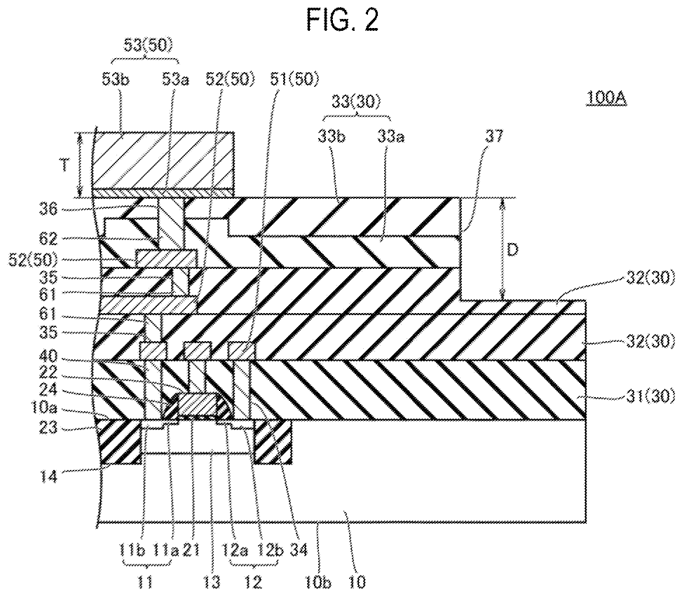

FIG. 1 is a plan view of the semiconductor device 100A. Further, it is noted that a wiring 53 is not shown in FIG. 1. FIG. 2 is a cross-sectional view taken along line II-II in FIG. 1. As shown in FIGS. 1 and 2, the semiconductor device 100A includes a semiconductor substrate 10, a gate insulating film 21, a gate 22, an insulating film 23, a sidewall spacer 24, a plurality of interlayer insulating films 30, a contact plug 40, a plurality of wirings 50, a via plug 61, and a via plug 62.

The semiconductor substrate 10 is made of, for example, single crystal silicon (Si). The semiconductor substrate 10 has a first main surface 10a and a second main surface 10b. The first main surface 10a and the second main surface 10b are end surfaces of the semiconductor substrate 10 in the thickness direction. The second main surface 10b is the opposite surface to the first main surface 10a. The semiconductor substrate 10 includes a source region 11, a drain region 12, and a well region 13.

The source region 11 and the drain region 12 are arranged in the first main surface 10a. The source region 11 and the drain region 12 are arranged with a space therebetween. The conductivity type of the source region 11 and the conductivity type of the drain region 12 are a first conductivity type. The first conductivity type is an n-type or a p-type.

The source region 11 has a first portion 11a and a second portion 11b. The first portion 11a is closer to the drain region 12 than the second portion 11b. The dopant concentration in the first portion 11a is lower than the dopant concentration in the second portion 11b. That is, the source region 11 has an LDD (Lightly Doped Diffusion) structure. The drain region 12 has a first portion 12a and a second portion 12b. The first portion 12a is closer to the source region 11 than the second portion 12b. The dopant concentration in the first portion 12a is lower than the dopant concentration in the second portion 12b. That is, the drain region 12 has an LDD structure.

The well region 13 is arranged in the first main surface 10a so as to surround the source region 11 and the drain region 12. The conductivity type of the well region 13 is a second conductivity type. The second conductivity type is the opposite conductivity type to the first conductivity type.

The gate insulating film 21 is arranged on the first main surface 10a between the source region 11 and the drain region 12. The gate insulating film 21 is made of, for example, silicon oxide. The gate 22 is arranged on the gate insulating film 21. The gate 22 is made of, for example, impurity-doped polycrystalline silicon. The source region 11, the drain region 12, the well region 13, the gate insulating film 21, and the gate 22 constitute a transistor.

A trench 14 is formed in the first main surface 10a. The trench 14 is formed so as to surround the well region 13 in a plan view. An insulating film 23 is embedded in the trench 14. The insulating film 23 is made of, for example, silicon oxide. That is, the trench 14 and the insulating film 23 have an STI (Shallow Trench Isolation) structure which isolates one transistor from another transistor. However, a LOCOS (Local Oxidation of Silicon) structure may be used instead of the STI structure.

The sidewall spacer 24 is arranged on the first portions 11a and 12a so as to contact the side surface of the gate 22. The sidewall spacer 24 is made of, for example, silicon nitride.

Among the plurality of interlayer insulating films 30, the one closest to the semiconductor substrate 10 is referred to as an interlayer insulating film 31. Among the plurality of interlayer insulating films 30, the one farthest from the semiconductor substrate 10 is referred to as an interlayer insulating film 33. Among the plurality of interlayer insulating films 30, the one located between the interlayer insulating film 31 and the interlayer insulating film 33 is referred to as an interlayer insulating film 32. Among the plurality of wirings 50, the one arranged on the interlayer insulating film 31 is referred to as a wiring 51. Among the plurality of wirings 50, the one arranged on the interlayer insulating film 32 is referred to as a wiring 52. Among the plurality of wirings 50, the one arranged on the interlayer insulating film 33 is referred to as a wiring 53. That is, the wiring 53 is the uppermost layer wiring.

The interlayer insulating film 31 is arranged on the semiconductor substrate 10 (on the first main surface 10a) so as to cover the gate insulating film 21, the gate 22, the insulating film 23, and the sidewall spacer 24. A contact hole 34 is formed in the interlayer insulating film 31. The contact hole 34 penetrates the interlayer insulating film 31 along the thickness direction. The source region 11 (the second portion 11b), the drain region 12 (the second portion 12b), or the gate 22 is exposed through the contact hole 34. The interlayer insulating film 31 is made of, for example, silicon oxide.

The contact plug 40 is embedded in the contact hole 34. A lower end of the contact plug 40 is electrically connected to the source region 11 (the second portion 11b), the drain region 12 (the second portion 12b), or the gate 22. The contact plug 40 is made of, for example, tungsten. The wiring 51 is arranged on the interlayer insulating film 31. The wiring 51 is electrically connected to an upper end of the contact plug 40. The wiring 51 is made of aluminum or an aluminum alloy.

The interlayer insulating film 32 is arranged on the interlayer insulating film 31 or on another interlayer insulating film 32. A via hole 35 is formed in the interlayer insulating film 32. The via hole 35 penetrates the interlayer insulating film 32 along the thickness direction. The via plug 61 is embedded in the via hole 35. A lower end of the via plug 61 is electrically connected to the wiring 51 or the wiring 52. An upper end of the via plug 61 is electrically connected to the wiring 52. The interlayer insulating film 32 is made of, for example, silicon oxide. The wiring 52 is made of, for example, aluminum or an aluminum alloy. The via plug 61 is made of, for example, tungsten.

A via hole 36 is formed in the interlayer insulating film 33. The via hole 36 penetrates the interlayer insulating film 33 along the thickness direction. The via plug 62 is embedded in the via hole 36. A lower end of the via plug 62 is electrically connected to the wiring 52. An upper end of the via plug 62 is electrically connected to the wiring 53. The via plug 62 is made of, for example, tungsten.

The interlayer insulating film 33 includes a first layer 33a and a second layer 33b. The first layer 33a is arranged on the interlayer insulating film 32 so as to cover the wiring 52. The first layer 33a is made of, for example, silicon oxide. The second layer 33b is arranged on the first layer 33a. The second layer 33b is made of, for example, silicon nitride.

The wiring 53 includes a seed layer 53a and a wiring body portion 53b. The seed layer 53a is arranged on the interlayer insulating film 33. The seed layer 53a is configured by stacking, for example, a titanium layer and a copper layer. The wiring body portion 53b is made of copper or a copper alloy. It is assumed that the thickness of the wiring 53 is a thickness T. The thickness T is, for example, 4 μm or more. The thickness T is, for example, m or less.

A trench 37 is formed in the upper surface of the interlayer insulating film 33. The trench 37 extends along the outer edge of the interlayer insulating film 33 in a plan view. The bottom of the trench 37 may reach, for example, the interlayer insulating film 32. The bottom of the trench 37 may not reach the interlayer insulating film 32 (the bottom of the trench 37 may be located in the interlayer insulating film 33). It is assumed that the depth of the trench 37 is a depth D. The depth D is a distance between the upper surface of the interlayer insulating film 33 and the bottom of the trench 37. The depth D is, for example, 1 μm or more and 6 μm or less.

### <Method of Manufacturing Semiconductor Device 100A>

A method of manufacturing the semiconductor device 100A will be described below.

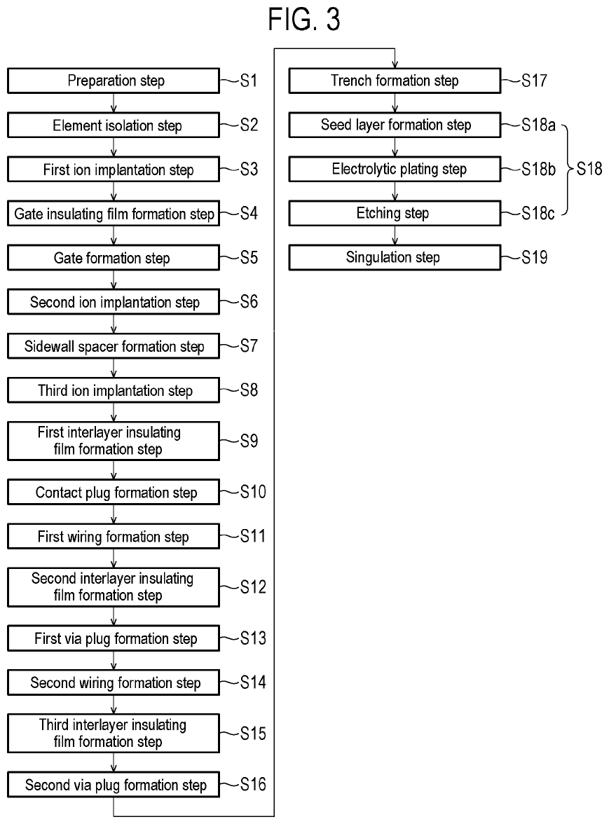

FIG. 3 is a manufacturing process diagram of the semiconductor device 100A. As shown in FIG. 3, the method of manufacturing the semiconductor device 100A includes a preparation step S1, an element isolation step S2, a first ion implantation step S3, a gate insulating film formation step S4, a gate formation step S5, a second ion implantation step S6, a sidewall spacer formation step S7, and a third ion implantation step S8.

The method of manufacturing the semiconductor device 100A further includes a first interlayer insulating film formation step S9, a contact plug formation step S10, a first wiring formation step S11, a second interlayer insulating film formation step S12, a first via plug formation step S13, a second wiring formation step S14, a third interlayer insulating film formation step S15, a second via plug formation step S16, a trench formation step S17, a third wiring formation step S18, and a singulation step S19.

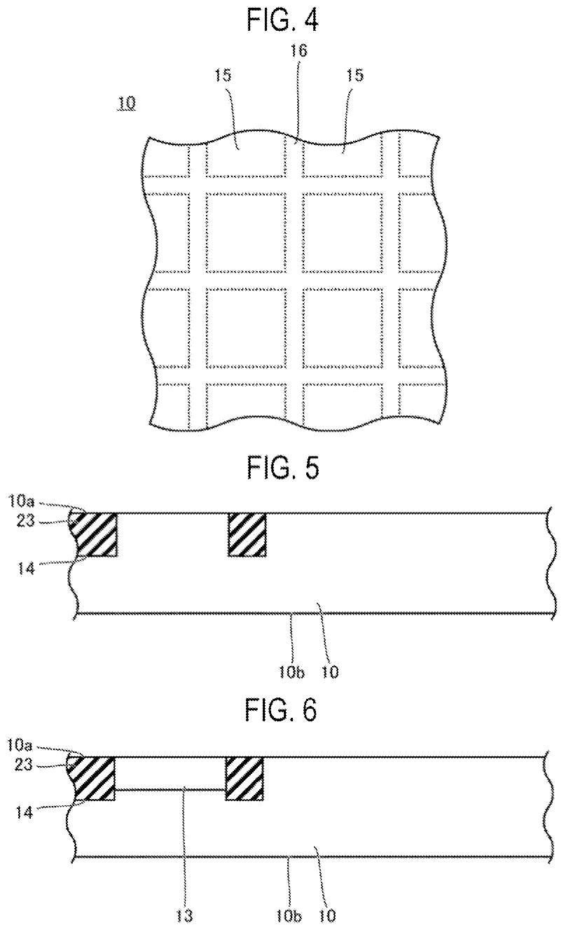

In the preparation step Sb, the semiconductor substrate 10 is prepared. The semiconductor substrate 10 prepared in the preparation step Sb is not singulated. FIG. 4 is a plan view of the semiconductor substrate 10 prepared in the preparation step Sb. As shown in FIG. 4, the semiconductor substrate 10 prepared in the preparation step S1 includes a plurality of element forming regions 15 and a scribe region 16 in a plan view. The scribe region 16 is located between two adjacent element formation regions 15. From another point of view, the element formation regions 15 are surrounded by the scribe region 16 in a plan view.

FIG. 5 is a cross-sectional view for explaining the device isolation step S2. As shown in FIG. 5, in the element isolation step S2, the trench 14 is formed and the insulating film 23 is embedded in the trench 14. The trench 14 is formed by dry-etching the semiconductor substrate 10 using a hard mask formed on the first main surface 10a. The insulating film 23 is formed by embedding the constituent material of the insulating film 23 in the trench 14 by, for example, CVD (Chemical Vapor Deposition), and removing the constituent material of the insulating film 23 protruding from the trench 14 by, for example, CMP (Chemical Mechanical Polishing). After forming the insulating film 23, the hard mask is removed.

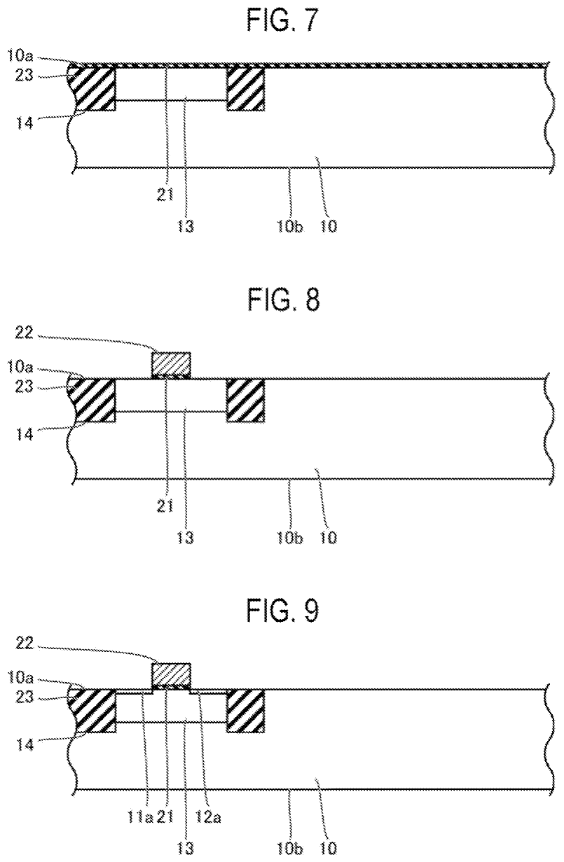

FIG. 6 is a cross-sectional view for explaining the first ion implantation step S3. As shown in FIG. 6, in the first ion implantation step S3, the well region 13 is formed by ion implantation. FIG. 7 is a cross-sectional view for explaining the gate insulating film formation step S4. As shown in FIG. 7, in the gate insulating film formation step S4, the gate insulating film 21 is formed by, for example, thermal oxidation.

FIG. 8 is a cross-sectional view for explaining the gate formation step S5. As shown in FIG. 8, the gate 22 is formed in the gate formation step S5. The gate 22 is formed by forming a film with the constituent material of the gate 22 by, for example, CVD and etching the film-formed constituent material of the gate 22 using a resist pattern patterned by photolithography as a mask. The above resist pattern is removed after the gate 22 is formed. FIG. 9 is a cross-sectional view for explaining the second ion implantation step S6. As shown in FIG. 9, in the second ion implantation step S6, the first portion 11a and the first portion 12a are formed by ion implantation.

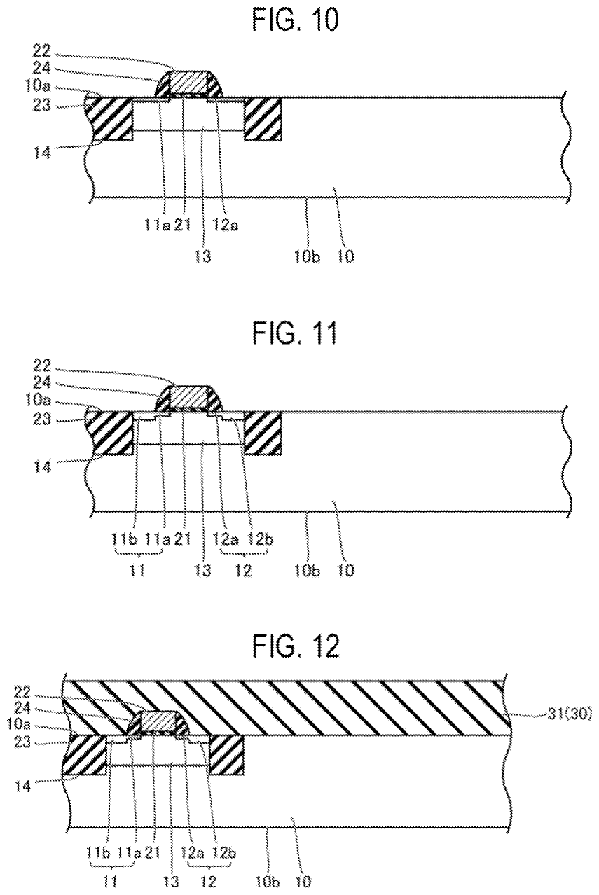

FIG. 10 is a cross-sectional view for explaining the sidewall spacer formation step S7. As shown in FIG. 10, the sidewall spacer 24 is formed in the sidewall spacer formation step S7. The sidewall spacer 24 is formed by forming a film with the constituent material of the sidewall spacer 24 by, for example, CVD and etching back the film-formed constituent material of the sidewall spacer 24. FIG. 11 is a cross-sectional view for explaining the third ion implantation step S8. As shown in FIG. 11, in the third ion implantation step S8, the second portion 11b and the second portion 12b are formed by ion implantation.

FIG. 12 is a cross-sectional view for explaining the first interlayer insulating film formation step S9. As shown in FIG. 11, the interlayer insulating film 31 is formed in the first interlayer insulating film formation step S9. The interlayer insulating film 31 is formed by forming a film with the constituent material of the interlayer insulating film 31 by CVD or the like and planarizing the film-formed constituent material of the interlayer insulating film 31 by CMP or the like.

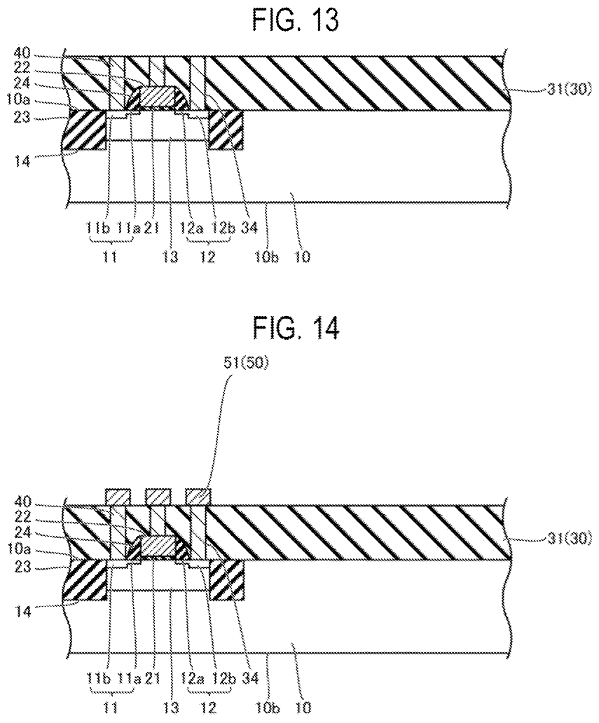

FIG. 13 is a cross-sectional view for explaining the contact plug formation step S10. As shown in FIG. 13, the contact hole 34 and the contact plug 40 are formed in the contact plug formation step S10. The contact hole 34 is formed by dry-etching the interlayer insulating film 31 using a resist pattern formed by photolithography as a mask. The above resist pattern is removed after the contact hole 34 is formed. The contact plug 40 is formed by embedding the constituent material of the contact plug 40 in the contact hole 34 by, for example, CVD and removing the constituent material of the contact plug 40 protruding from the contact hole 34 by, for example, CMP.

FIG. 14 is a cross-sectional view for explaining the first wiring formation step S11. As shown in FIG. 14, the wiring 51 is formed in the first wiring formation step S11. The wiring 51 is formed by forming a film with the constituent material of the wiring 51 by sputtering or the like, and dry-etching the film-formed constituent material of the wiring 51 using a resist pattern formed by photolithography as a mask. The above resist pattern is removed after the wiring 51 is formed.

FIG. 15 is a cross-sectional view for explaining the second interlayer insulating film formation step S12. As shown in FIG. 15, the interlayer insulating film 32 is formed in the second interlayer insulating film formation step S12. The interlayer insulating film 32 is formed by forming a film with the constituent material of the interlayer insulating film 32 by CVD or the like and planarizing the film-formed constituent material of the interlayer insulating film 32 by CMP or the like.

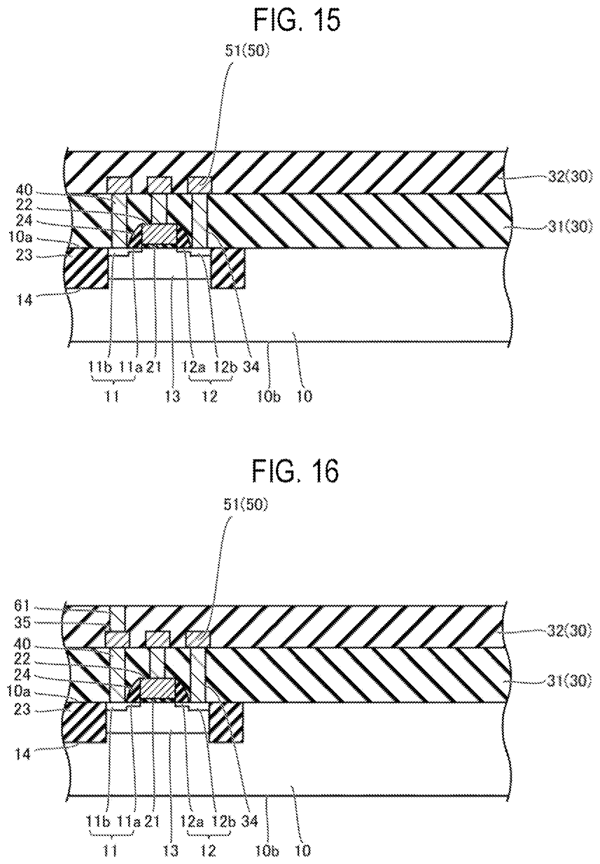

FIG. 16 is a cross-sectional view for explaining the first via plug formation step S13. As shown in FIG. 16, the via hole 35 and the via plug 61 are formed in the first via plug formation step S13. The via hole 35 is formed by dry-etching the interlayer insulating film 32 using a resist pattern formed by photolithography as a mask. The above resist pattern is removed after the via hole 35 is formed. The via plug 61 is formed by embedding the constituent material of the via plug 61 in the via hole 35 by, for example, CVD and removing the constituent material of the via plug 61 protruding from the via hole 35 by, for example, CMP.

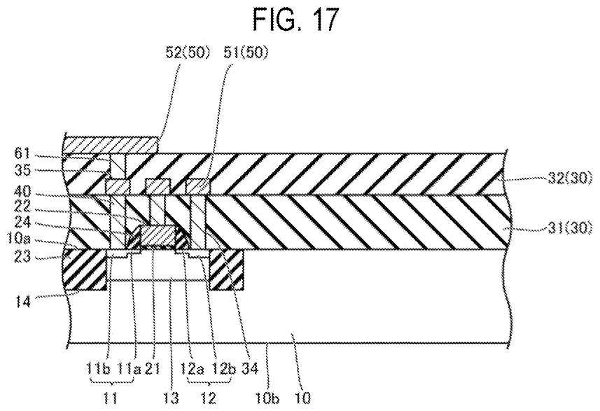

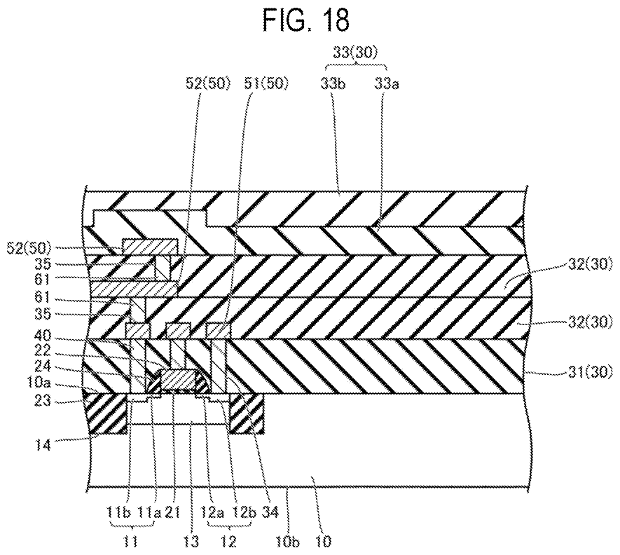

FIG. 17 is a cross-sectional view for explaining the second wiring formation step S14. As shown in FIG. 17, the wiring 52 is formed in the second wiring formation step S14. The wiring 52 is formed by forming a film with the constituent material of the wiring 52 by sputtering or the like, and dry-etching the film-formed constituent material of the wiring 52 using a resist pattern formed by photolithography as a mask. The above resist pattern is removed after the wiring 52 is formed. The second interlayer insulating film formation step S12, the first via plug formation step S13, and the second wiring formation step S14 are repeated according to the number of interlayer insulating films 32 and the number of wirings 52.

FIG. 18 is a cross-sectional view for explaining the third interlayer insulating film formation step S15. As shown in FIG. 18, the interlayer insulating film 33 (the first layer 33a and the second layer 33b) is formed in the third interlayer insulating film formation step S15. The interlayer insulating film 33 is formed by sequentially forming films with the constituent material of the first layer 33a and the constituent material of the second layer 33b by, for example, CVD and planarizing the film-formed constituent material of the second layer 33b by, for example, CMP.

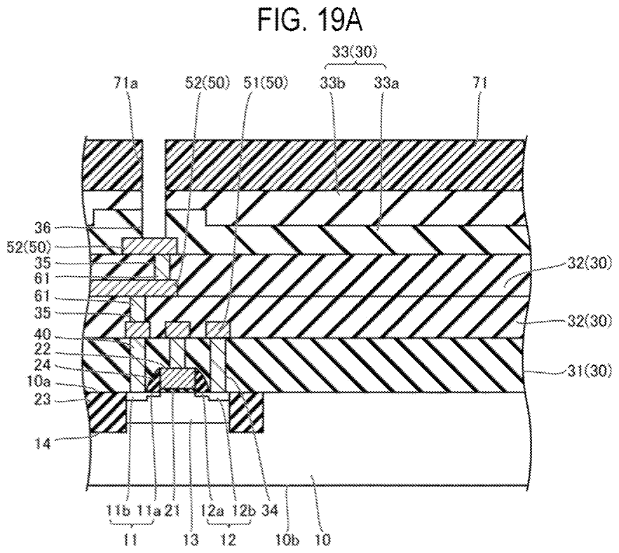

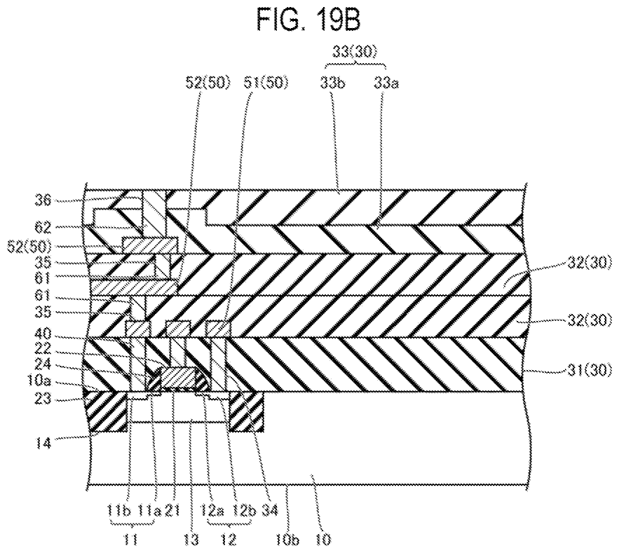

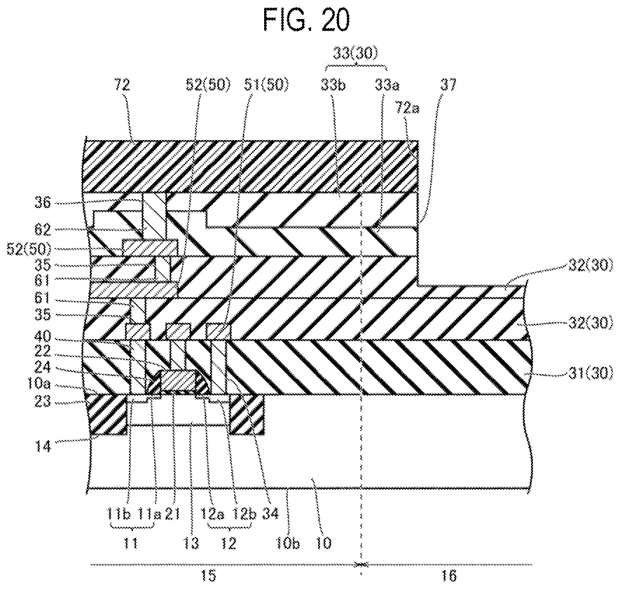

FIG. 19A is a first cross-sectional view for explaining the second via plug formation step S16. As shown in FIG. 19A, the via hole 36 is first formed in the second via plug formation step S16. In forming the via hole 36, first, a resist pattern 71 is formed on the interlayer insulating film 33 by photolithography. The resist pattern 71 includes an opening 71a. Next, the interlayer insulating film 33 exposed through the opening 71a is dry-etched using the resist pattern 71 as a mask. Thus, the via hole 36 is formed. The resist pattern 71 is removed after the via hole 36 is formed.

FIG. 19B is a second cross-sectional view for explaining the second via plug formation step S16. As shown in FIG. 19B, the second via plug 62 is formed in the second via plug formation step S16. The via plug 62 is formed by embedding the constituent material of the via plug 62 in the via hole 36 by, for example, CVD and removing the constituent material of the via plug 62 protruding from the via hole 36 by, for example, CMP.

FIG. 20 is a cross-sectional view for explaining the trench formation step S17. As shown in FIG. 20, the trench 37 is formed in the trench formation step S17. The trench 37 is formed so as to overlap the scribe region 16 in a plan view. In forming the trench 37, first, a resist pattern 72 is formed on the interlayer insulating film 33 by photolithography. The resist pattern 72 includes an opening 72a. Second, the interlayer insulating film 33 exposed through the opening 72a is dry-etched using the resist pattern 72 as a mask. Thus, the trench 37 is formed. The resist pattern 72 is removed after the trench 37 is formed.

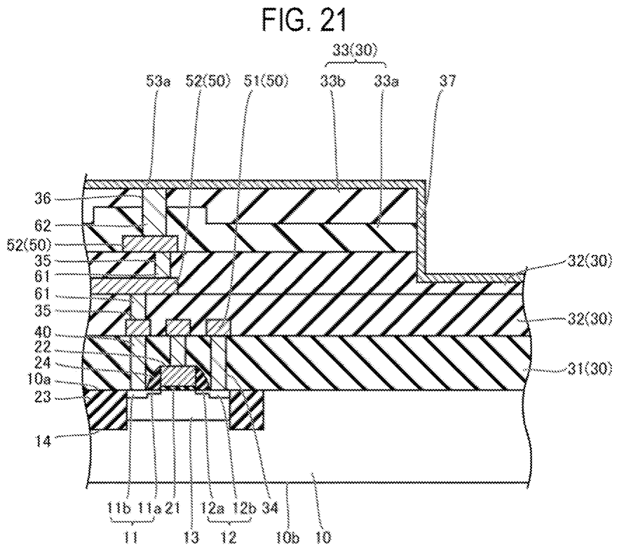

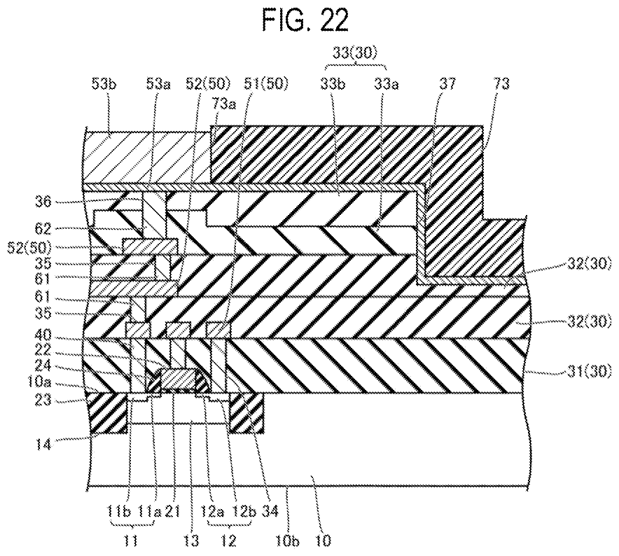

As shown in FIG. 3, the third wiring formation step S18 includes a seed layer formation step S18a, an electrolytic plating step S18b, and an etching step S18c. FIG. 21 is a cross-sectional view for explaining the seed layer formation step S18a. As shown in FIG. 21, in the seed layer formation step S18a, the seed layer 53a is formed by forming a film with the constituent material of the seed layer 53a by, for example, sputtering.

FIG. 22 is a cross-sectional view for explaining the electrolytic plating step S18b. As shown in FIG. 22, the wiring body portion 53b is formed in the electrolytic plating step S18b. In forming the wiring body portion 53b, first, a resist pattern 73 is formed on the seed layer 53a by photolithography. The resist pattern 73 has an opening 73a.

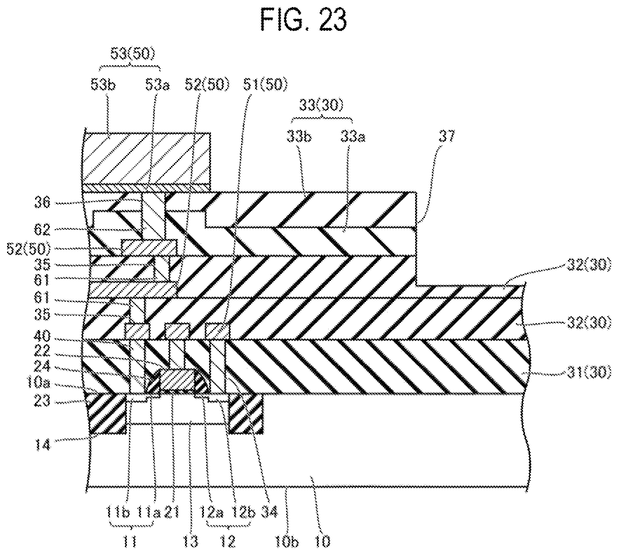

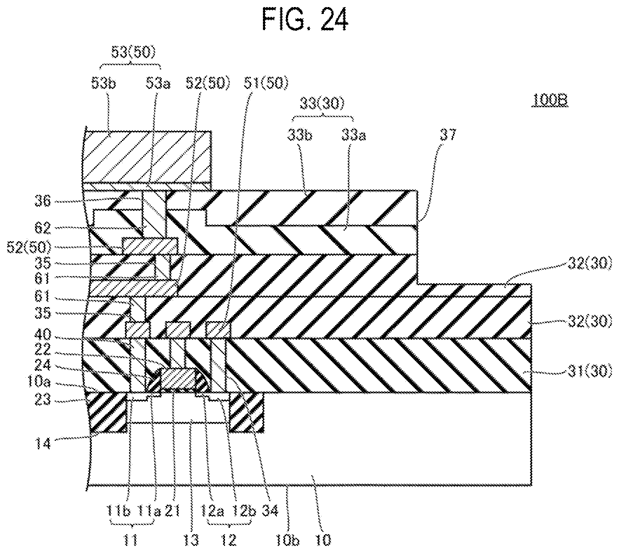

Second, the wiring body portion 53b is formed on the seed layer 53a, which is exposed through the opening 73a, by electroplating. The resist pattern 73 is removed after the wiring body portion 53b is formed. FIG. 23 is a cross-sectional view for explaining the etching step S18c. As shown in FIG. 23, in the etching step S18c, the seed layer 53a under the resist pattern 73 is removed by wet etching using the wiring body portion 53b as a mask.

In the dicing step S19, the semiconductor substrate 10 in the scribe region 16 and the plurality of interlayer insulating films 30 on the scribe region 16 are cut in the wafer formed as described above, so that a plurality of semiconductor devices 100 having the structure shown in FIGS. 1 and 2 is obtained. As described above, since the scribe region 16 surrounds the element forming region 15 in a plan view, the trench 37 remains along the outer edge of the interlayer insulating film 33.

### ≥Effects of Semiconductor Device 100A>

The effects of the semiconductor device 100A will be described below.

The constituent material of the wiring body portion 53b is copper or a copper alloy, and has a larger coefficient of thermal expansion than, for example, aluminum. Therefore, a wafer having the wiring body portion 53b is likely to warp due to the thermal expansion of the wiring body portion 53b. Such warping becomes particularly noticeable when the thickness T is large (for example, when the thickness T is 4 μm or more). However, the trench 37 is formed in the above wafer. As a result, the rigidity of the wafer is lowered, and the warping is easily corrected by the weight of the wafer itself. Therefore, even in the semiconductor device 100A diced from the above wafer, the warping is suppressed.

### Second Embodiment

A semiconductor device according to a second embodiment will be described. The semiconductor device according to the second embodiment is referred to as a semiconductor device 100B. Here, points different from the semiconductor device 100A will be mainly described, and duplicate explanation thereof will not be repeated.

### <Configuration of Semiconductor Device 100B>

A configuration of the semiconductor device 100B will be described below.

FIG. 24 is a cross-sectional view of the semiconductor device 100B. FIG. 24 shows a cross section at a location corresponding to line II-II in FIG. 2. As shown in FIG. 24, the semiconductor device 100B includes a semiconductor substrate 10, a gate insulating film 21, a gate 22, an insulating film 23, a sidewall spacer 24, an interlayer insulating film 31, an interlayer insulating film 32, an interlayer insulating film 33, a contact plug 40, a wiring 51, a wiring 52, a wiring 53, a via plug 61, and a via plug 62. In the semiconductor device 100B, the wiring 53 includes a seed layer 53a and a wiring body portion 53b. In the semiconductor device 100B, a trench 37 is formed in the upper surface of the interlayer insulating film 33 along the outer edge of the interlayer insulating film 33 in a plan view. Regarding these points, the configuration of the semiconductor device 100B is the same as the configuration of the semiconductor device 100A.

In the semiconductor device 100B, the constituent material of the seed layer 53a is the same as the constituent material of the via plug 62. In this regard, the configuration of the semiconductor device 100B is different from the configuration of the semiconductor device 100A.

A method of manufacturing the semiconductor device 100B will be described below.

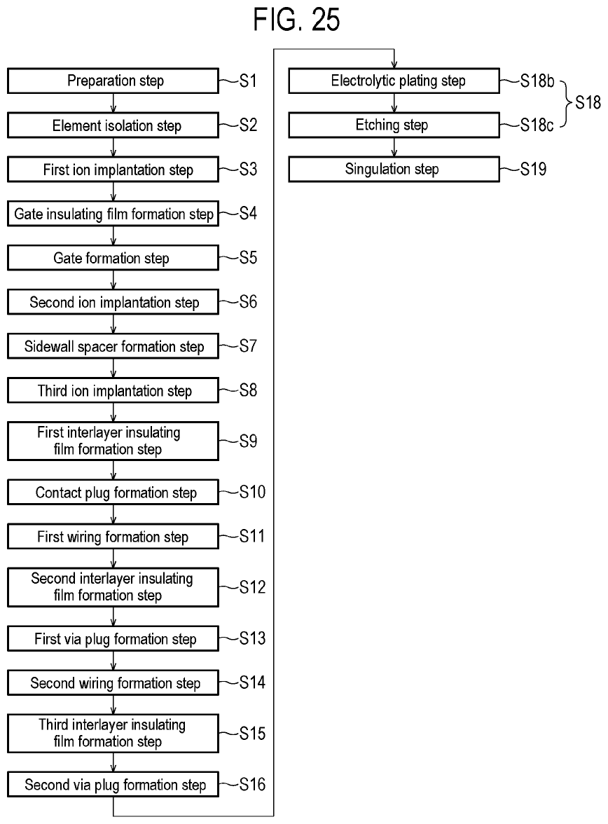

FIG. 25 is a manufacturing process diagram of the semiconductor device 100B. As shown in FIG. 25, the method of manufacturing the semiconductor device 100B includes a preparation step Sb, an element isolation step S2, a first ion implantation step S3, a gate insulating film formation step S4, a gate formation step S5, a second ion implantation step S6, a sidewall spacer formation step S7, and a third ion implantation step S8. The method of manufacturing the semiconductor device 100B further includes a contact plug formation step S10, a first wiring formation step S11, a second interlayer insulating film formation step S12, a first via plug formation step S13, a second wiring formation step S14, a third interlayer insulating film formation step S15, a second via plug formation step S16, a third wiring formation step S18, and a singulation step S19. Regarding these points, the method of manufacturing the semiconductor device 100B is the same as the method of manufacturing the semiconductor device 100A.

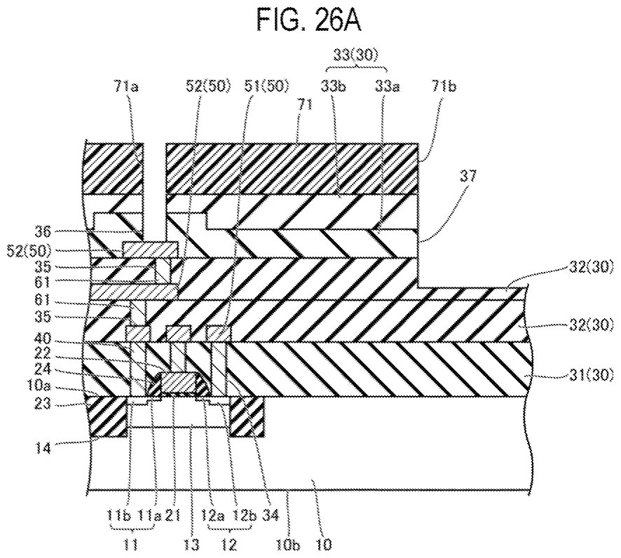

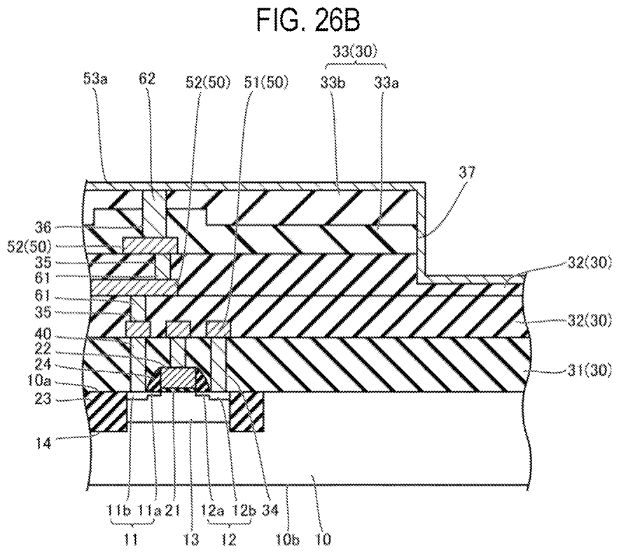

The method of manufacturing the semiconductor device 100B does not include the trench formation step S17. FIG. 26A is a first cross-sectional view for explaining the second via plug formation step S16 in the method of manufacturing the semiconductor device 100B. As shown in FIG. 26A, a resist pattern 71 includes an opening 71b in addition to an opening 71a. Therefore, in the method of manufacturing the semiconductor device 100B, a via hole 36 and the trench 37 are simultaneously formed by etching using the resist pattern 71 as a mask.

FIG. 26B is a second cross-sectional view for explaining the second via plug formation step S16 in the method of manufacturing the semiconductor device 100B. As shown in FIG. 26B, in the method of manufacturing the semiconductor device 100B, in the second via plug formation step S16, the constituent material of the via plug 62 is embedded in the via hole 36, but the constituent material of the via plug 62, which is film-formed on the interlayer insulating film 33 and on the side surface and bottom surface of the trench 37, is not removed. The constituent material of the via plug 62, which is film-formed on the side surface and bottom surface of the trench 37, functions as a seed layer 53a. Therefore, in the method of manufacturing the semiconductor device 100B, the third wiring formation step S18 does not include the seed layer formation step S18a (see FIG. 25). Regarding these points, the method of manufacturing the semiconductor device 100B is different from the method of manufacturing the semiconductor device 100A.

### <Effects of Semiconductor Device 100B>

The effects of the semiconductor device 100B will be described below.

The manufacturing process of the semiconductor device 100B is simplified as compared with the semiconductor device 100A. More specifically, when manufacturing the semiconductor device 100B, it is not necessary to separately perform the trench formation step S17 and the seed layer formation step S18a, and the removal of the constituent material of the via plug 62 in the second via plug formation step S16 can be omitted.

If the seed layer 53a does not sufficiently cover the bottom surface and side surface of the trench 37, an electroplating step S18b may be hindered. When manufacturing the semiconductor device 100B, since the seed layer 53a is formed simultaneously with the via plug 62, the seed layer 53a can be formed using CVD. CVD has better step coverage than sputtering. Therefore, in the semiconductor device 100B, even when the trench 37 is formed deeper than in the semiconductor device 100A, the bottom surface and side surface of the trench 37 are easily covered with the seed layer 53a. When the trench 37 is formed deeply, the rigidity of the wafer is further lowered, so that warping can be further suppressed in the semiconductor device 100B.

### (Supplementary Notes)

As described above, the embodiments of the present disclosure include the following configurations.

### <Supplementary Note 1>

A semiconductor device including:
an interlayer insulating film; and
a wiring of an uppermost layer arranged on the interlayer insulating film,
wherein the wiring includes a seed layer arranged on the interlayer insulating film and a wiring body portion arranged on the seed layer,
wherein a constituent material of the wiring body portion is copper or a copper alloy, and
wherein a trench is formed in an upper surface of the interlayer insulating film along an outer edge of the interlayer insulating film in a plan view.

### <Supplementary Note 2>

The semiconductor device of Supplementary Note 1, wherein the wiring has a thickness of 4 μm or more.

### <Supplementary Note 3>

The semiconductor device of Supplementary Note 1 or 2, further including: a via plug electrically connected to the wiring,
wherein a via hole in which the via plug is embedded is formed in the interlayer insulating film, and
wherein a constituent material of the seed layer is different from a constituent material of the via plug.

### <Supplementary Note 4>

The semiconductor device of Supplementary Note 1 or 2, further including: a via plug electrically connected to the wiring,
wherein a via hole in which the via plug is embedded is formed in the interlayer insulating film, and
wherein a constituent material of the seed layer is the same as a constituent material of the via plug.

### <Supplementary Note 5>

The semiconductor device of any one of Supplementary Notes 1 to 4, wherein the trench has a depth of 1 μm or more and 6 μm or less.

### <Supplementary Note 6>

A method of manufacturing a semiconductor device, including:
forming an interlayer insulating film;
forming a via hole in the interlayer insulating film;
embedding a via plug in the via hole;
forming a wiring of an uppermost layer on the interlayer insulating film; and
forming a trench in an upper surface of the interlayer insulating film,
wherein the wiring is formed by forming a seed layer on the interlayer insulating film, forming a first resist pattern having a first opening on the seed layer, forming a wiring body portion on the seed layer exposed through the first opening by performing electroplating, and removing the seed layer by etching using the wiring body portion as a mask,
wherein a constituent material of the wiring body portion is copper or a copper alloy,
wherein the interlayer insulating film is located above a semiconductor substrate,
wherein the semiconductor substrate includes, in a plan view, a plurality of element forming regions and a scribe region between two adjacent ones of the plurality of element forming regions, and
wherein the trench is formed so as to overlap the scribe region in a plan view.

### <Supplementary Note 7>

The method of Supplementary Note 6, further including:
forming a second resist pattern having a second opening on the interlayer insulating film; and
forming a third resist pattern having a third opening on the seed layer,
wherein the via hole is formed by etching the interlayer insulating film exposed through the second opening using the second resist pattern as a mask, and
wherein the trench is formed by etching the interlayer insulating film exposed through the third opening using the third resist pattern as a mask.

### <Supplementary Note 8>

The method of Supplementary Note 6, further including forming a fourth resist pattern having a fourth opening and a fifth opening on the interlayer insulating film,
wherein the via hole and the trench are formed by etching the interlayer insulating film exposed through the fourth opening and the interlayer insulating film exposed through the fifth opening, respectively, using the fourth resist pattern as a mask, and
wherein when the via plug is embedded in the via hole, the seed layer is formed on the interlayer insulating film using a same constituent material as the via plug.

Although the embodiments of the present disclosure have been described as above, it is also possible to modify the above-described embodiments in various ways. In addition, the scope of the present disclosure is not limited to the above-described embodiments. The scope of the present disclosure is indicated by the claims and is intended to include all changes within the meaning and scope equivalent to the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
an interlayer insulating film; and
a wiring of an uppermost layer arranged on the interlayer insulating film,
wherein the wiring includes a seed layer arranged on the interlayer insulating film and a wiring body portion arranged on the seed layer,
wherein a constituent material of the wiring body portion is copper or a copper alloy, and
wherein a trench is formed in an upper surface of the interlayer insulating film along an outer edge of the interlayer insulating film in a plan view.

2. The semiconductor device of claim 1, wherein the wiring has a thickness of 4 μm or more.

3. The semiconductor device of claim 1, further comprising a via plug electrically connected to the wiring,
wherein a via hole in which the via plug is embedded is formed in the interlayer insulating film, and
wherein a constituent material of the seed layer is different from a constituent material of the via plug.

4. The semiconductor device of claim 1, further comprising a via plug electrically connected to the wiring,
wherein a via hole in which the via plug is embedded is formed in the interlayer insulating film, and
wherein a constituent material of the seed layer is the same as a constituent material of the via plug.

5. The semiconductor device of claim 1, wherein the trench has a depth of 1 μm or more and 6 μm or less.

6. A method of manufacturing a semiconductor device, comprising:
forming an interlayer insulating film;
forming a via hole in the interlayer insulating film;
embedding a via plug in the via hole;
forming a wiring of an uppermost layer on the interlayer insulating film; and
forming a trench in an upper surface of the interlayer insulating film,
wherein the wiring is formed by forming a seed layer on the interlayer insulating film, forming a first resist pattern having a first opening on the seed layer, forming a wiring body portion on the seed layer exposed through the first opening by performing electroplating, and removing the seed layer by etching using the wiring body portion as a mask,
wherein a constituent material of the wiring body portion is copper or a copper alloy,
wherein the interlayer insulating film is located above a semiconductor substrate,
wherein the semiconductor substrate includes, in a plan view, a plurality of element forming regions and a scribe region between two adjacent ones of the plurality of element forming regions, and
wherein the trench is formed so as to overlap the scribe region in a plan view.

7. The method of claim 6, further comprising:
forming a second resist pattern having a second opening on the interlayer insulating film; and
forming a third resist pattern having a third opening on the seed layer,
wherein the via hole is formed by etching the interlayer insulating film exposed through the second opening using the second resist pattern as a mask, and
wherein the trench is formed by etching the interlayer insulating film exposed through the third opening using the third resist pattern as a mask.

8. The method of claim 6, further comprising forming a fourth resist pattern having a fourth opening and a fifth opening on the interlayer insulating film,
wherein the via hole and the trench are formed by etching the interlayer insulating film exposed through the fourth opening and the interlayer insulating film exposed through the fifth opening, respectively, using the fourth resist pattern as a mask, and
wherein when the via plug is embedded in the via hole, the seed layer is formed on the interlayer insulating film using a same constituent material as the via plug.
